(19) United States
(12) Patent Application Publication
(10) Pub. No.: US 2026/0254085 A1
(43) Pub. Date: Aug. 27, 2026

(54) WAVEGUIDE STRUCTURE, CIRCUIT BOARD AND MANUFACTURING METHOD OF CIRCUIT BOARD

(71) Applicant: UNIMICRON TECHNOLOGY CORP., Taoyuan City (TW)

(72) Inventors: Hsin-Hung LEE, Taoyuan City (TW); Chen-Yang TSENG, Taoyuan City (TW); Hsuan-Yu LAI, Taoyuan City (TW); Ching CHANG, Taoyuan City (TW)

(73) Assignee: UNIMICRON TECHNOLOGY CORP., Taoyuan City (TW)

(21) Appl. No.: 19/176,676

(22) Filed: Apr. 11, 2025

(30) Foreign Application Priority Data
Feb. 26, 2025 (TW) 114107009

(51) Int. Cl. H01P 3/02; H05K 1/02; H05K 1/181; H05K 3/46

(52) U.S. Cl. CPC H01P 3/02; H05K 1/0237; H05K 1/181; H05K 3/46

(57) ABSTRACT

The disclosure provides waveguide structure, circuit board and manufacturing method of the circuit board. The waveguide structure includes dielectric layer, first and second metal layers, first conductive through vias and second conductive through via. The first and second metal layers are disposed on two opposite sides of dielectric layer, respectively. The first metal layer has bottom surface, top surface and notches. The notches penetrate through bottom surface and top surface. The notches together form connecting area in a symmetric polygonal shape. The first metal layer is configured to be connected to the antenna in the connecting area. The first and second conductive through vias are disposed in the dielectric layer and electrically connect the first metal layer and the second metal layer. The first conductive through vias are arranged around the connecting area. The second conductive through via is located in at least one gap between adjacent notches.

### CROSS-REFERENCE TO RELATED APPLICATIONS

This non-provisional application claims priority under 35 U.S.C. § 119 (a) on Patent Application No(s). 114107009 filed in Taiwan, R.O.C. on Feb. 26th, 2025, the entire contents of which are hereby incorporated by reference.

### Technical Field

The disclosure relates to a waveguide structure, a circuit board and a manufacturing method of the circuit board, more particularly to a waveguide structure including one or more conductive through vias, a circuit board including the waveguide structure and a manufacturing method of the circuit board.

### Background

With the rapid development of the wireless communication technology, the application of the radar product is increasingly widened. Recently, a 4D imaging radar that is able to perform accurate detection in three-dimensional space is developed.

However, in conventional radar product, the chip of the circuit board and the antenna are located on the same surface of the same layer, and are electrically connected to each other by one or more transmission lines. Thus, such configuration is unable to allow the 4D imaging radar to have low signal loss and include a large number of antennas.

### SUMMARY

The disclosure provides a waveguide structure, a circuit board and a manufacturing method of the circuit board to reduce the signal loss of the antennas via the waveguide structure and to allow more antennas to be electrically connected to the circuit board via the waveguide structure.

One embodiment of this disclosure provides a waveguide structure configured to be connected to an antenna and including a dielectric layer, a first metal layer, a second metal layer, a plurality of first conductive through vias and at least one second conductive through via. The first metal layer and the second metal layer are disposed on two opposite sides of the dielectric layer, respectively. The first metal layer has a bottom surface, a top surface and a plurality of notches. The bottom surface faces toward the dielectric layer. The top surface faces away from the bottom surface. The plurality of notches penetrates through the bottom surface and the top surface. The plurality of notches together forms a connecting area that is in a symmetric polygonal shape. The first metal layer is configured to be connected to the antenna in the connecting area. The plurality of first conductive through vias is disposed in the dielectric layer and electrically connects the first metal layer and the second metal layer. The plurality of first conductive through vias is arranged around the connecting area. The at least one second conductive through via is disposed in the dielectric layer and electrically connects the first metal layer and the second metal layer. The at least one second conductive through via is located in at least one gap between adjacent ones of the plurality of notches.

In an embodiment of the disclosure, there are four notches and the connecting area is in a diamond shape.

In an embodiment of the disclosure, the at least one second conductive through via includes a plurality of second conductive through vias. Two gaps are formed between adjacent four of the plurality of notches, and the plurality of second conductive through vias is located in the two gaps, respectively.

In an embodiment of the disclosure, the plurality of second conductive through vias located in each of the two gaps is arranged in an array.

In an embodiment of the disclosure, the first metal layer further has a connecting recess penetrating through the bottom surface and the top surface and connecting two of the plurality of notches.

In an embodiment of the disclosure, the waveguide structure further includes a plurality of third conductive through vias. The plurality of third conductive through vias is disposed in the dielectric layer and electrically connects the first metal layer and the second metal layer, and the plurality of third conductive through vias is arranged around the connecting recess.

In an embodiment of the disclosure, the waveguide structure further includes a fourth conductive via. The fourth conductive via is disposed in the dielectric layer and electrically connects the first metal layer and the second metal layer, and the connecting recess surrounds the fourth conductive via.

In an embodiment of the disclosure, at least one of the plurality of first conductive through vias and the at least one second conductive through via is made of silver.

In an embodiment of the disclosure, the first metal layer further has a side surface connecting the bottom surface and the top surface, and at least one of the plurality of notches is located on the side surface.

In an embodiment of the disclosure, the plurality of first conductive through vias is misaligned with each other along an extension direction of one of the plurality of notches adjacent thereto.

Another embodiment of this disclosure provides a circuit board including a circuit substrate, a chip, a core layer, a first conductive structure and the waveguide structure. The chip is electrically connected to the circuit substrate. The core layer is electrically connected to the circuit substrate. The chip is located in the core layer. The first conductive structure is disposed in the core layer and electrically connected to the circuit substrate. The second metal layer is disposed on the core layer and electrically connected to the first conductive structure.

In an embodiment of the disclosure, the first conductive structure is a coaxial via.

In an embodiment of the disclosure, the circuit board further includes a core substrate and a second conductive structure. The core substrate is disposed on the core layer. The second conductive structure is disposed in the core substrate. The second metal layer is disposed on the core layer via the core substrate, and the second metal layer is electrically connected to the first conductive structure via the second conductive structure.

Still another embodiment of this disclosure provides a manufacturing method of circuit board including: providing a circuit substrate and a chip electrically connected to the circuit substrate; forming a core layer electrically connected to the circuit substrate and surrounding the chip; and forming a first conductive structure electrically connected to the circuit substrate in the core layer, disposing the second metal layer of the waveguide structure on the core layer, and electrically connecting the second metal layer to the first conductive structure.

In an embodiment of the disclosure, before forming the first conductive structure electrically connected to the circuit substrate in the core layer, disposing the second metal layer on the core layer, and electrically connecting the second metal layer to the first conductive structure, the manufacturing method of circuit board further comprises: forming a second conductive structure in a core substrate, disposing the core substrate on the core layer, and electrically connecting the second conductive structure to the first conductive structure. The second metal layer is disposed on the core layer via the core substrate, and the second metal layer is electrically connected to the first conductive structure via the second conductive structure.

According to the waveguide structure, the circuit board and the manufacturing method of the circuit board disclosed by above embodiments, the first conductive through vias are arranged around the connecting area, and at least one second conductive through via is located in at least one gap between adjacent notches. Thus, with the waveguide structure including the first conductive through vias and the second conductive through via, the antenna connected to the waveguide structure is allowed to have lower signal loss. In addition, more antennas are allowed to be electrically connected to the circuit board via the waveguide structure. In this way, the space utilization of the circuit board is improved. Additionally, the cost for realizing the low signal loss of the antenna is reduced by omitting the material with low dielectric constant and high cost that is required in a conventional case that the antenna is formed inside the circuit board.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIGS. 1 to 4 show a manufacturing method of a circuit board according to a first embodiment of the disclosure;

FIG. 5 is a partially enlarged top view of the circuit board in FIG. 4;

FIG. 6 is a partially enlarged view of the circuit board in FIG. 5; and

FIGS. 7 to 12 show a manufacturing method of a circuit board according to a second embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

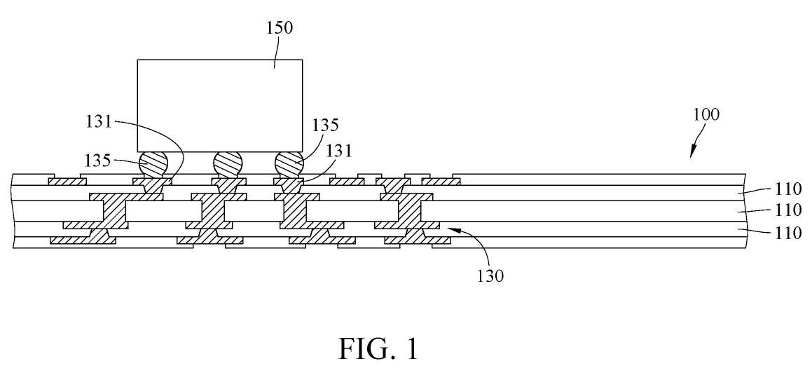

Please refer to FIGS. 1 to 4 showing a manufacturing method of a circuit board 10 according to a first embodiment of the disclosure. First, as shown in FIG. 1, a circuit substrate 100 and a chip 150 electrically connected to the circuit substrate 100 are provided. The circuit substrate 100 includes, for example, a plurality of dielectric layers 110 and a circuit structure 130. The dielectric layers 110 are stacked on one another. The circuit structure 130 is disposed in the dielectric layer 110 and includes, for example, a plurality of circuit layers, a plurality of conductive blind vias and a plurality of conductive through vias. In addition, the circuit structure 130 further includes, for example, a plurality of contacts 131. The contacts 131 are electrically connected to the chip 150 via, for example, solder balls 135.

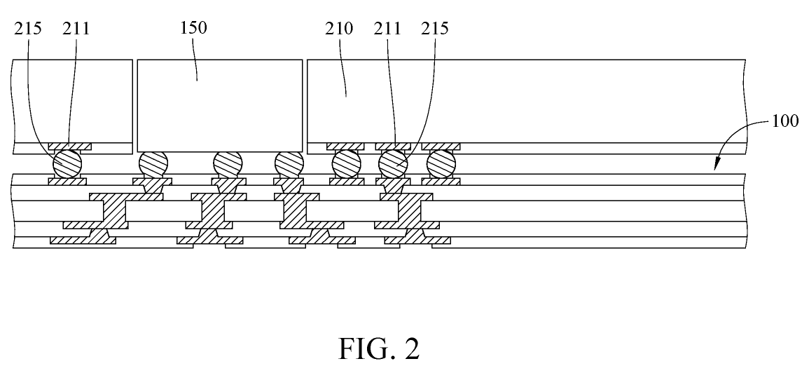

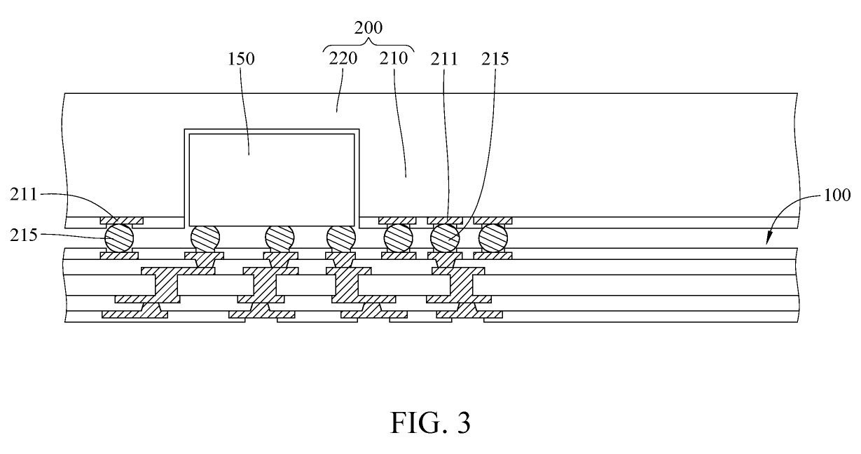

Then, as shown in FIGS. 2 and 3, a core layer 200 electrically connected to the circuit substrate 100 and surrounding the chip 150 is formed. For example, in this embodiment, forming the core layer 200 includes forming a first core layer 210 electrically connected to the circuit substrate 100 and surrounding the chip 150 (as shown in FIG. 2) and forming a second core layer 220 stacked on the first core layer 210 (as shown in FIG. 3). The first core layer 210 has, for example, a plurality of contacts 211. The circuit structure 130 further has, for example, a plurality of contacts 132. The contacts 211 are electrically connected to the contacts 132 via, for example, solder balls 215. The core layer 200 is made of metal, such as copper or aluminum, so as to facilitate the cooling of the chip 150. In this embodiment, there is, for example, a narrow gap between the core layer 200 and the chip 150 to allow the core layer 200 to have a certain degree of manufacturing tolerance. Note that such gap is very narrow in practical product and thus can exist without disturbing the core layer 200 from facilitating the cooling of the chip 150.

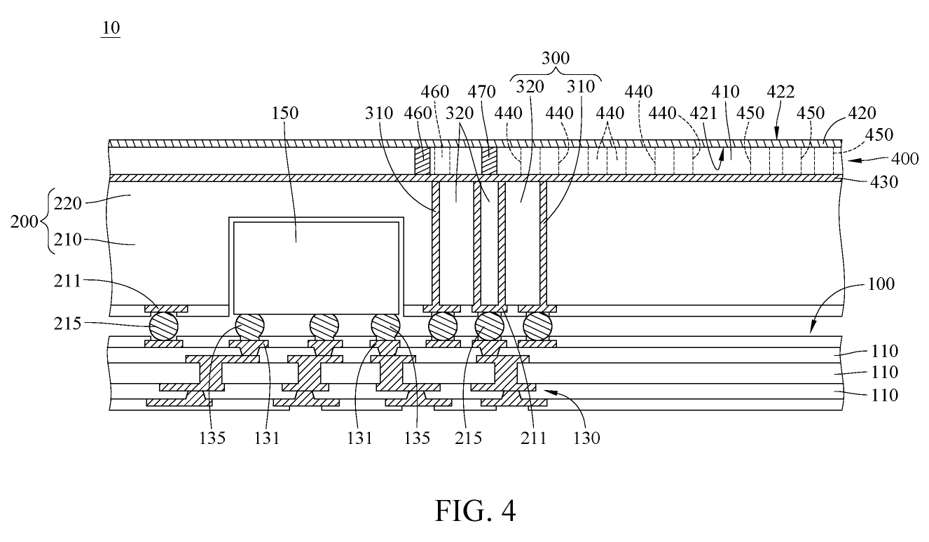

Then, as shown in FIG. 4, a conductive structure 300 electrically connected to the circuit substrate 100 is formed in the first core layer 210 and the second core layer 220 of the core layer 200, and a second metal layer 430 of a waveguide structure 400 is disposed on the second core layer 220 of the core layer 200 and electrically connected to the conductive structure 300. So far, the manufacture of the circuit board 10 is completed. The detailed structure of the waveguide structure 400 will be described later.

In this embodiment, the conductive structure 300 is, for example, a coaxial via, and includes a plurality of conductive through vias 310 and a plurality of dielectric materials 320. The conductive through vias 310 penetrate through the first core layer 210 and the second core layer 220, and electrically connect the contacts 211 and the second metal layer 430. The dielectric materials 320 are disposed in the conductive through vias 310 or disposed between the conductive through vias 310, respectively.

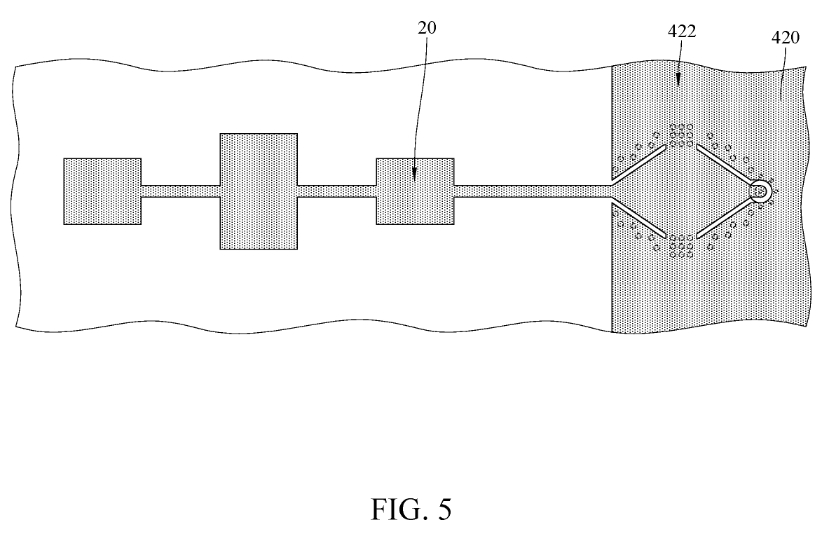

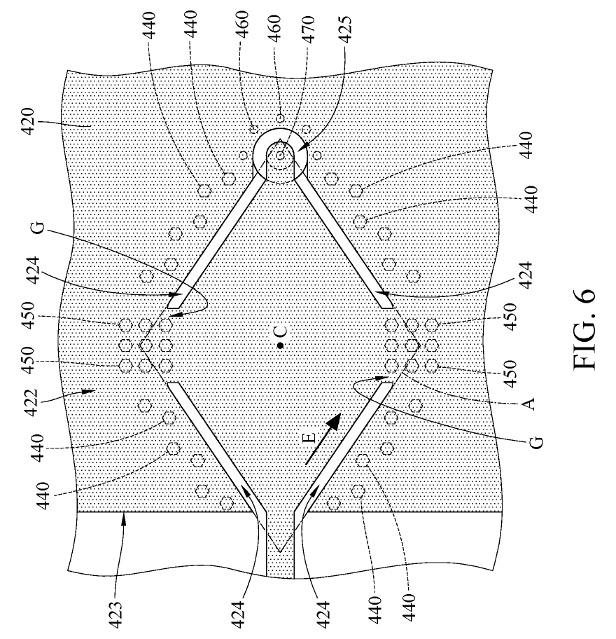

Hereinafter, please refer to FIGS. 4 to 6 for the detailed structure of the waveguide structure 400. FIG. 5 is a partially enlarged top view of the circuit board 10 in FIG. 4. FIG. 6 is a partially enlarged view of the circuit board 10 in FIG. 5.

The waveguide structure 400 is, for example, a substrate-integrated waveguide (SIW). The waveguide structure 400 is configured to be connected to an antenna 20 and includes a dielectric layer 410, a first metal layer 420, the second metal layer 430, a plurality of first conductive through vias 440, a plurality of second conductive through vias 450, a plurality of third conductive through vias 460 and a fourth conductive via 470.

The first metal layer 420 and the second metal layer 430 are disposed on two opposite sides of the dielectric layer 410, respectively.

The first metal layer 420 has a bottom surface 421, a top surface 422, a side surface 423, a plurality of notches 424 and a connecting recess 425. The bottom surface 421 faces toward the dielectric layer 410. The top surface 422 faces away from the bottom surface 421. The side surface 423 connects the bottom surface 421 and the top surface 422. The notches 424 penetrate through the bottom surface 421 and the top surface 422. The notches 424 together form a connecting area A that is in a symmetric polygonal shape. The first metal layer 420 is configured to be connected to the antenna 20 in the connecting area A. That is, a part of the first metal layer 420 located in the connecting area A is configured to be connected to the antenna 20. Note that the connecting area A may, for example, be understood as a space having the same thickness or height as the first metal layer 420 in a stacking direction of the dielectric layer 410, the first metal layer 420 and the second metal layer 430. Furthermore, in this embodiment, for example, there are four notches 424 and the connecting area A is in a diamond shape, but the disclosure is not limited thereto. In other embodiments, the number, the shape or the arrangement of the notches may be adjusted to make the connecting area to be in any types of symmetric polygonal shapes, such as a triangular shape and a rectangular shape.

Moreover, as least one of the notches 424 is located on the side surface 423. In this embodiment, there are, for example, two notches 424 located on the side surface 423.

The connecting recess 425 penetrates through the bottom surface 421 and the top surface 422, and connects two of the notches 424. Also, the connecting recess 425 is in, for example, an arc shape.

The first conductive through vias 440 are disposed in the dielectric layer 410, and electrically connect the first metal layer 420 and the second metal layer 430. The first conductive through vias 440 are arranged around the connecting area A. That is, the notches 424 are located between a geometric center C of the connecting area A and the first conductive through vias 440. Further, in this embodiment, each notch 424 corresponds to, for example, multiple first conductive through vias 440, and the first conductive through vias 440 are misaligned with one another along an extension direction E of the notch 424 adjacent thereto.

The second conductive through vias 450 are disposed in the dielectric layer 410, and electrically connect the first metal layer 420 and the second metal layer 430. In this embodiment, two gaps G are formed between four adjacent notches 424, with the second conductive through vias 450 being located in the two gaps G, respectively. In addition, in this embodiment, the second conductive through vias 450 in each gap G are, for example, arranged in an array, such as a 3x3 array. Note that in other embodiments, there may be one gap formed by the notches, and there may be one second conductive through via.

The third conductive through vias 460 are disposed in the dielectric layer 410, and electrically connect the first metal layer 420 and the second metal layer 430. The third conductive through vias 460 are arranged around the connecting recess 425.

The fourth conductive via 470 is disposed in the dielectric layer 410, and electrically connects the first metal layer 420 and the second metal layer 430. The connecting recess 425 surrounds the fourth conductive via 470.

In addition, in this embodiment, at least one of the first conductive through vias 440, the second conductive through vias 450, the third conductive through vias 460 and the fourth conductive via 470 is/are made of silver, and thus the antenna 20 has a lower signal loss.

In this embodiment, the first conductive through vias 440 are arranged around the connecting area A, and at least one second conductive through via 450 is located in at least one gap G between adjacent notches 424. Thus, with the waveguide structure 400 including the first conductive through vias 440 and the second conductive through via 450, the antenna 20 connected to the waveguide structure 400 is allowed to have lower signal loss. In addition, more antennas 20 are allowed to be electrically connected to the circuit board 10 via the waveguide structure 400. In this way, the space utilization of the circuit board 10 is improved. Additionally, the cost for realizing the low signal loss of the antenna 20 is reduced by omitting the material with low dielectric constant and high cost that is required in a conventional case that the antenna is formed inside the circuit board.

Other embodiments are described below for illustrative purposes. It is to be noted that the following embodiments use the reference numerals and a part of the contents of the above embodiments, the same reference numerals are used to denote the same or similar elements, and the description of the same technical contents is omitted. For the description of the omitted part, reference may be made to the above embodiments, and details are not described in the following embodiments.

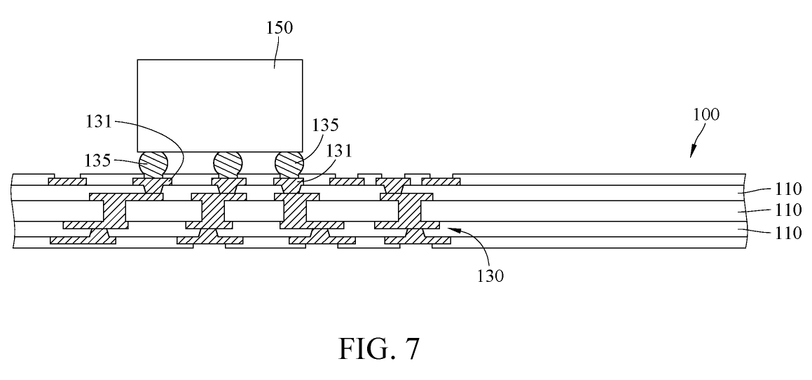

Please refer to FIGS. 7 to 12 showing a manufacturing method of a circuit board 10a according to a second embodiment of the disclosure.

First, as shown in FIG. 7, the circuit substrate 100 and the chip 150 electrically connected to the circuit substrate 100 are provided. The detailed structure of the circuit substrate 100 has been described above and thus the repeated descriptions are omitted.

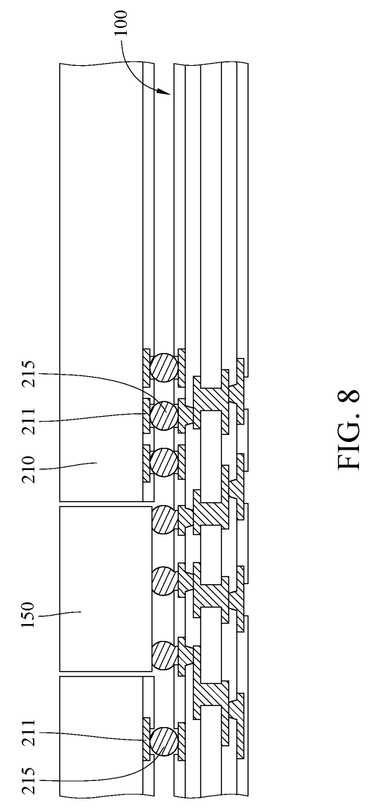

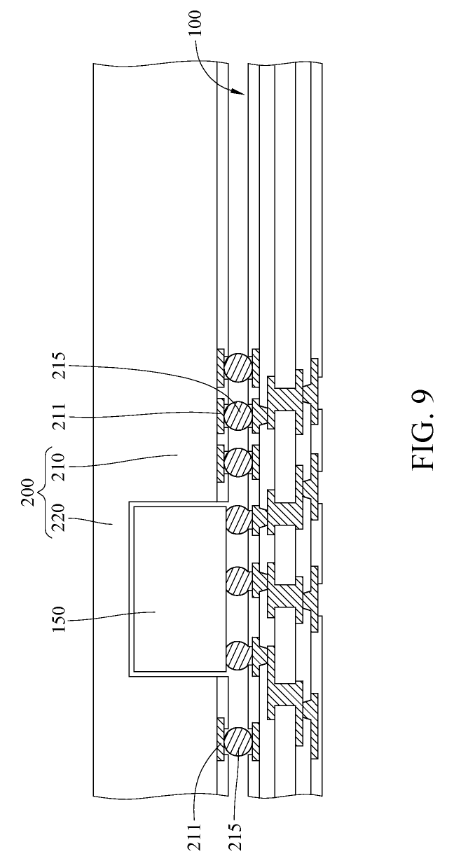

Then, as shown in FIGS. 8 and 9, the core layer 200 electrically connected to the circuit substrate 100 and surrounding the chip 150 is formed. For example, forming the core layer 200 includes forming the first core layer 210 electrically connected to the circuit substrate 100 and surrounding the chip 150 (as shown in FIG. 8) and forming the second core layer 220 stacked on the first core layer 210 (as shown in FIG. 9).

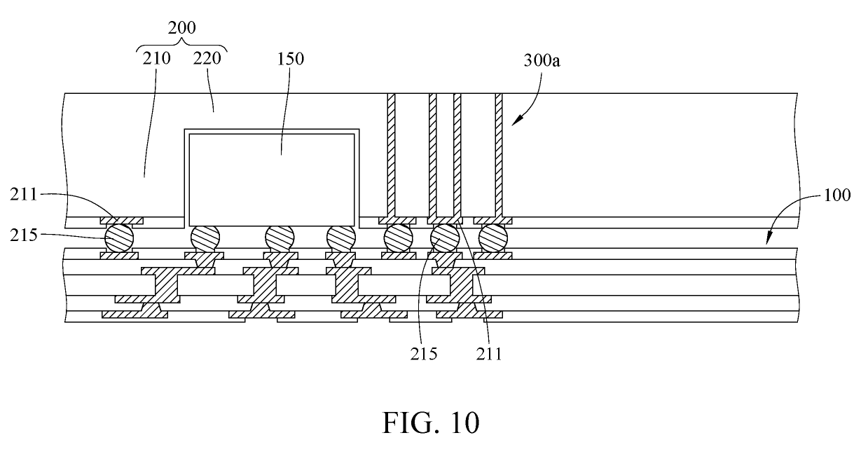

Then, as shown in FIG. 10, a first conductive structure 300a electrically connected to the circuit substrate 100 is formed in the first core layer 210 and the second core layer 220 of the core layer 200.

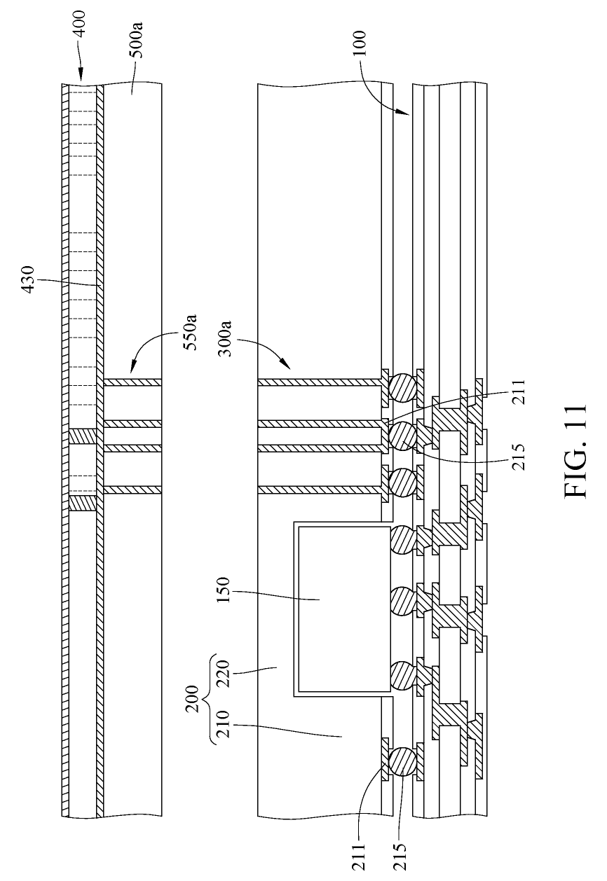

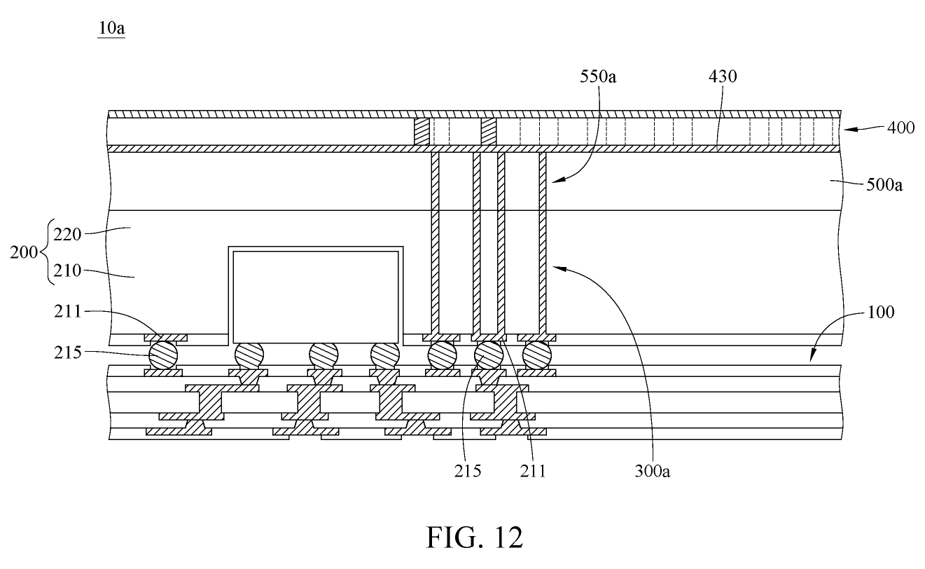

Then, as shown in FIGS. 11 and 12, a second conductive structure 550a is formed in a core substrate 500a, the core substrate 500a is disposed on the core layer 200, and the second conductive structure 550a is electrically connected to the first conductive structure 300a. The second metal layer 430 is disposed on the core substrate 500a. That is, the second metal layer 430 is disposed on the core layer 200 via the core substrate 500a. The second metal layer 430 is electrically connected to the first conductive structure 300a via the second conductive structure 550a. The detailed structures of the first conductive structure 300a and the second conductive structure 550a are similar to that of the conductive structure 300 in the first embodiment, and thus the repeated descriptions thereof are omitted. So far, the manufacture of the circuit board 10a is completed. The circuit board 10a of this embodiment further includes the core substrate 500a and the second conductive structure 550a comparing to the circuit board 10 in the first embodiment, and thus the application of the circuit board 10a is more flexible.

According to the waveguide structure, the circuit board and the manufacturing method of the circuit board disclosed by above embodiments, the first conductive through vias are arranged around the connecting area, and at least one second conductive through via is located in at least one gap between adjacent notches. Thus, with the waveguide structure including the first conductive through vias and the second conductive through via, the antenna connected to the waveguide structure is allowed to have lower signal loss. In addition, more antennas are allowed to be electrically connected to the circuit board via the waveguide structure. In this way, the space utilization of the circuit board is improved. Additionally, the cost for realizing the low signal loss of the antenna is reduced by omitting the material with low dielectric constant and high cost that is required in a conventional case that the antenna is formed inside the circuit board.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A waveguide structure, configured to be connected to an antenna and comprising:
a dielectric layer;
a first metal layer and a second metal layer, disposed on two opposite sides of the dielectric layer, respectively, wherein the first metal layer has a bottom surface, a top surface and a plurality of notches, the bottom surface faces toward the dielectric layer, the top surface faces away from the bottom surface, the plurality of notches penetrates through the bottom surface and the top surface, the plurality of notches together forms a connecting area that is in a symmetric polygonal shape, and the first metal layer is configured to be connected to the antenna in the connecting area;
a plurality of first conductive through vias, disposed in the dielectric layer and electrically connecting the first metal layer and the second metal layer, wherein the plurality of first conductive through vias is arranged around the connecting area; and
at least one second conductive through via, disposed in the dielectric layer and electrically connecting the first metal layer and the second metal layer, wherein the at least one second conductive through via is located in at least one gap between adjacent ones of the plurality of notches.

2. The waveguide structure according to claim 1, wherein there are four notches and the connecting area is in a diamond shape.

3. The waveguide structure according to claim 2, wherein the at least one second conductive through via comprises a plurality of second conductive through vias, two gaps are formed between adjacent four of the plurality of notches, and the plurality of second conductive through vias is located in the two gaps, respectively.

4. The waveguide structure according to claim 3, wherein the plurality of second conductive through vias located in each of the two gaps is arranged in an array.

5. The waveguide structure according to claim 2, wherein the first metal layer further has a connecting recess penetrating through the bottom surface and the top surface and connecting two of the plurality of notches.

6. The waveguide structure according to claim 5, further comprising a plurality of third conductive through vias, wherein the plurality of third conductive through vias is disposed in the dielectric layer and electrically connects the first metal layer and the second metal layer, and the plurality of third conductive through vias is arranged around the connecting recess.

7. The waveguide structure according to claim 6, further comprising a fourth conductive via, wherein the fourth conductive via is disposed in the dielectric layer and electrically connects the first metal layer and the second metal layer, and the connecting recess surrounds the fourth conductive via.

8. The waveguide structure according to claim 1, wherein at least one of the plurality of first conductive through vias and the at least one second conductive through via is made of silver.

9. The waveguide structure according to claim 1, wherein the first metal layer further has a side surface connecting the bottom surface and the top surface, and at least one of the plurality of notches is located on the side surface.

10. The waveguide structure according to claim 1, wherein the plurality of first conductive through vias is misaligned with each other along an extension direction of one of the plurality of notches adjacent thereto.

11. A circuit board, comprising:
a circuit substrate;
a chip, electrically connected to the circuit substrate;
a core layer, electrically connected to the circuit substrate, wherein the chip is located in the core layer;
a first conductive structure, disposed in the core layer and electrically connected to the circuit substrate; and
the waveguide structure according to claim 1, wherein the second metal layer is disposed on the core layer and electrically connected to the first conductive structure.

12. The circuit board according to claim 11, wherein the first conductive structure is a coaxial via.

13. The circuit board according to claim 11, further comprising a core substrate and a second conductive structure, wherein the core substrate is disposed on the core layer, the second conductive structure is disposed in the core substrate, the second metal layer is disposed on the core layer via the core substrate, and the second metal layer is electrically connected to the first conductive structure via the second conductive structure.

14. A manufacturing method of circuit board, comprising:
providing a circuit substrate and a chip electrically connected to the circuit substrate;
forming a core layer electrically connected to the circuit substrate and surrounding the chip; and
forming a first conductive structure electrically connected to the circuit substrate in the core layer, disposing the second metal layer of the waveguide structure according to claim 1 on the core layer, and electrically connecting the second metal layer to the first conductive structure.

15. The manufacturing method of circuit board according to claim 14, wherein before forming the first conductive structure electrically connected to the circuit substrate in the core layer, disposing the second metal layer on the core layer, and electrically connecting the second metal layer to the first conductive structure, the manufacturing method of circuit board further comprises:
forming a second conductive structure in a core substrate, disposing the core substrate on the core layer, and electrically connecting the second conductive structure to the first conductive structure;
wherein the second metal layer is disposed on the core layer via the core substrate, and the second metal layer is electrically connected to the first conductive structure via the second conductive structure.
